(19) United States
(12) Patent Application Publication
(10) Pub. No.: US 2026/0001190 A1
(43) Pub. Date: Jan. 1, 2026

(54) WAFER GRINDING METHODS

(71) Applicant: STATS ChipPAC Pte. Ltd., Singapore (SG)

(72) Inventors: YiJing Eric CHONG, Singapore (SG); Rowena ZARATE, Singapore (SG); Marites ROQUE, Singapore (SG); PeiEe Linda CHUA, Singapore (SG); KaiChong CHAN, Singapore (SG)

(21) Appl. No.: 19/248,413

(22) Filed: Jun. 24, 2025

(30) Foreign Application Priority Data
Jun. 26, 2024 (CN) 202410839930.X

(51) Int. Cl. B24B 37/04; H01L 21/304

(52) U.S. Cl. CPC B24B 37/042; H01L 21/304

(57) ABSTRACT

A wafer grinding method comprises: providing a wafer base comprising a front side and a back side, wherein the front side comprises a solder ball area and an annular peripheral area surrounding the solder ball area; forming a patterned photoresist layer on the front side of the wafer base, wherein the patterned photoresist layer at least partially covers the annular peripheral area but exposes the solder ball area; forming solder balls on the solder ball area; attaching a back grinding tape on the front side to cover both the solder ball area and the annular peripheral area; and performing a back grinding process on the back side of the wafer base.

### TECHNICAL FIELD

The present application generally relates to manufacture of semiconductor devices, and more particularly, to wafer grinding methods.

### BACKGROUND OF THE INVENTION

The semiconductor industry is constantly faced with complex integration challenges as consumers want their electronics to be smaller, faster and higher performance with more and more functionality packed into a single device. One of the solutions is to reduce a size of a semiconductor device via a wafer grinding process to provide semiconductor dice with thinner profiles. Yet, when the wafer is ground and gets thinner, a wafer edge may be reduced to a sharp edge, which may be relatively weak. At a micro-level view, it can be observed that there is little structural support at this part of the wafer. Hence, application of uneven forces during grinding or stress relieving can easily create a crack. This crack can continue to spread during further handling and cause wafer edge chipping or even wafer cracking.

Thus, there exists a need for further improvement of the wafer grinding method.

### SUMMARY OF THE INVENTION

An objective of the present application is to provide an improved wafer grinding method with wafer strength reinforcement.

According to an aspect of the present application, a wafer grinding method is provided. The wafer grinding method comprises: providing a wafer base comprising a front side and a back side, wherein the front side comprises a solder ball area and an annular peripheral area surrounding the solder ball area; forming a patterned photoresist layer on the front side of the wafer base, wherein the patterned photoresist layer at least partially covers the annular peripheral area but exposes the solder ball area; forming solder balls on the solder ball area; attaching a back grinding tape on the front side to cover both the solder ball area and the annular peripheral area; and performing a back grinding process on the back side of the wafer base.

According to another aspect of the present application, a wafer grinding method is provided. The wafer grinding method comprises: providing a wafer base comprising a front side and a back side, wherein the front side comprises a solder ball area and an annular peripheral area surrounding the solder ball area, wherein the solder ball area is formed with solder balls; forming a patterned thermosetting material layer on the front side of the wafer base, wherein the patterned thermosetting material layer at least partially covers the annular peripheral area but exposes the solder ball area; attaching a back grinding tape on the front side to cover both the solder ball area and the annular peripheral area; and performing a back grinding process on the back side of the wafer base.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a plan view of a wafer base.

FIG. 1B illustrates a portion of the wafer base shown in FIG. 1A.

FIG. 1C illustrates a side view of a portion of the wafer base shown in FIG. 1A during a back grinding process.

FIG. 2A illustrates a plan view of a wafer base formed with edge support according to an embodiment of the present application.

FIG. 2B illustrates a portion of the wafer base shown in FIG. 2A.

FIG. 2C illustrates a side view of a portion of the wafer base shown in FIG. 2A during a back grinding process.

FIGS. 2D and 2E illustrate portions of the wafer base shown in FIG. 2A according to two other embodiments of the present application.

FIGS. 3A to 3G illustrate a portion of a wafer base in the steps for wafer grinding according to an embodiment of the present application.

FIGS. 4A to 4C illustrate a portion of a wafer base in the steps for wafer grinding according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

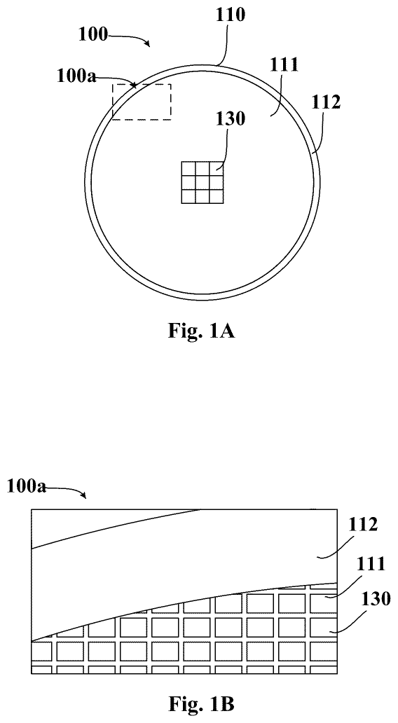

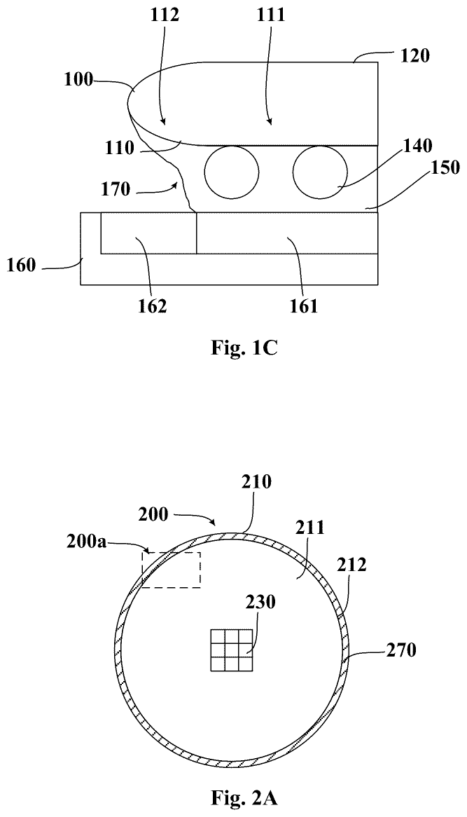

FIGS. 1A to 1C show a wafer base 100 prepared for a conventional wafer grinding process from different perspectives. FIG. 1A illustrates a plan view of the wafer base 100, FIG. 1B illustrates a portion 100a of the wafer base 100, and FIG. 1C illustrates a side view of a portion of the wafer base 100 during a back grinding process.

Referring to FIGS. 1A to 1C, the wafer base 100 may generally take a form of a circular plate which has various semiconductor units 130 (for illustration purpose, only 9 are shown). Specifically, a front side 110 of the wafer base 100 includes a solder ball area 111 and an annular peripheral area 112 surrounding the solder ball area 111. In the solder ball area 111, the semiconductor units 130 may be formed with solder balls 140 for electrical connection with other electrical devices.

During a back grinding process, the wafer base 100 is attached with a back grinding tape 150. The back grinding tape 150 provides support and protection to the active front surface 110 of the wafer base 100. Then the wafer base 100 can be placed on a chuck table 160 and a back side 120 of the wafer base 100, which is opposite to the front side 110, can be exposed for back grinding.

As shown in FIG. 1C, due to the nature of solder balls 140 formed on the front side 110 of the wafer base 100, the back grinding tape 150 on the annular peripheral area 112 may form a step profile 170, and hence, the annular peripheral area 112 may not have sufficient support underneath. Such step profile 170 is significant for high bumped (>120 μm) wafers. Further, the chuck table 160 usually has a center porous area 161 and a ceramic area 162. When grinding the high bumped wafers, the manufacturer usually uses a chuck table with a smaller porous area (286 mm) rather than a normal chuck table (with a porous area of 297 mm), such chuck table with the smaller porous area may also cause vacuum leakage underneath the annular peripheral area 112. Therefore, in the conventional wafer grinding process, the edge of the wafer base 100 is not fully supported, and therefore, the annular peripheral area 112 of the wafer base 100 subjects to a greater grinding stress, potential uneven grinding and high total thickness variations (TTV), which may lead to weaken edge, edge chipping and die crack.

To address the above issue, there is provided an improved wafer grinding method with better edge support at the annular peripheral area of the wafer base.

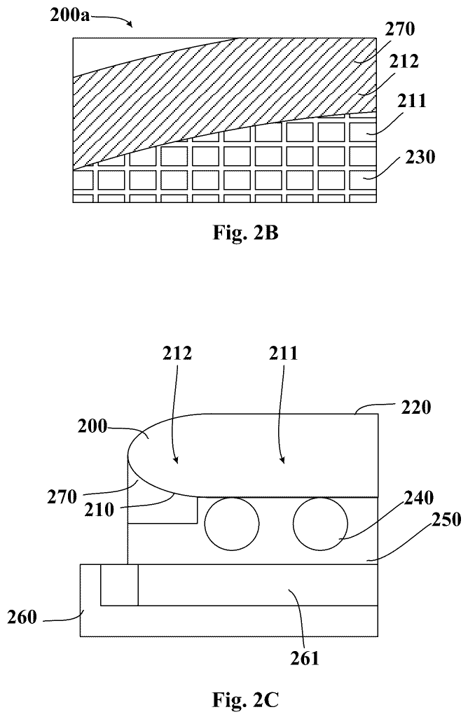

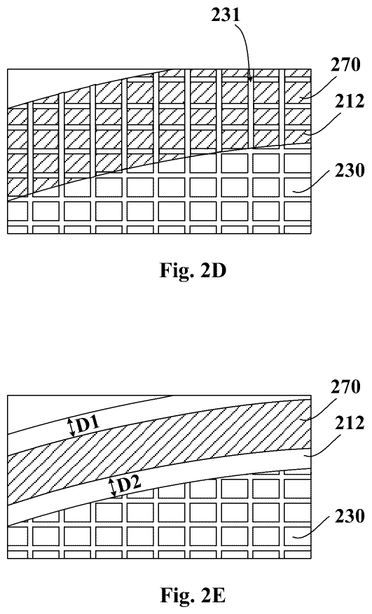

FIGS. 2A to 2C show a wafer base 200 prepared for a wafer grinding process from different perspectives according to an embodiment of the present application. FIG. 2A illustrates a plan view of the wafer base 200, FIG. 2B illustrates a portion 200a of the wafer base 200, and FIG. 2C illustrates a side view of a portion of the wafer base 200 during a back grinding process.

Different from the conventional back grinding process, it is proposed in the embodiment to form an edge support 270 on an annular peripheral area 212 of a front surface 210 of the wafer base 200. With such edge support 270, the annular peripheral area 212 has sufficient structural support underneath. Also, a chuck table with a normal porous area 261 (e.g., of 297 mm) can be used, and the annular peripheral area 212 is vacuumed similar as a solder ball area 211 of the front surface 210 of the wafer base 200. Therefore, grinding stress and damage to the wafer edge can be greatly mitigated, especially for thin wafers with high bumps. Also, the manufacturer would not need to purchase a chuck table with smaller porous area. Hence, the manufacture cost can be reduced.

The edge support 270 may take any desired forms on the annular peripheral area 212. In some embodiments, as shown in FIG. 2B, the edge support 270 may cover all of the annular peripheral area 212. In some embodiments, as shown in FIGS. 2D and 2E, the edge support 270 may partially cover the annular peripheral area 212. In some embodiments, as shown in FIG. 2D, the edge support 270 may expose a saw street 231 between semiconductor units 230 of the wafer base 200 to minimize dicing blade clogging during sawing, especially when a thin blade or very fine diamond blade is used. In some embodiments, as shown in FIG. 2E, the edge support 270 may be formed at a certain distance from either or both of the boundaries of the annular peripheral area 212. Specifically, there may be a distance D1 between an outer boundary of the annular peripheral area 212 and an outer boundary of the edge support 270, preferably ranging from 0.5 mm to 1.5 mm, more preferably 1 mm. Therefore, the back grinding tape 250 may stick to the wafer base 200 near the wafer edge. Similarly, there may be a distance D2 between an inner boundary of the annular peripheral area 212 and an inner boundary of the edge support 270, preferably ranging from 0.5 mm and 1.5 mm, more preferably 1 mm. Therefore, the back grinding tape 250 may stick to the wafer base 200 near the wafer edge. Also, the edge support 270 with such configuration remains enough room for the material of the back grinding tape 250 to conform to and fill up to the area between the edge support 270 and the outmost solder balls 240.

A height of the edge support 270 may vary as desired. Preferably, the height of the edge support 270 ranges from ½ to ¾ of an average height of the solder balls 240. Such height may minimize a gap in height between the solder balls 240 and a front side 210 of the wafer base 200, and still allow adequate coverage of the back grinding tape 250 to take place. Therefore, the back grinding tape 250 may easily and stably cover the solder balls 240 and an area between the outmost solder balls 240 and the edge support 270.

According to the embodiment of the present application, the edge support 270 may be a patterned photoresist layer or a patterned thermosetting material layer. These two materials allow better control on the height of the edge support. Details for wafer grinding with such edge supports are illustrated as below.

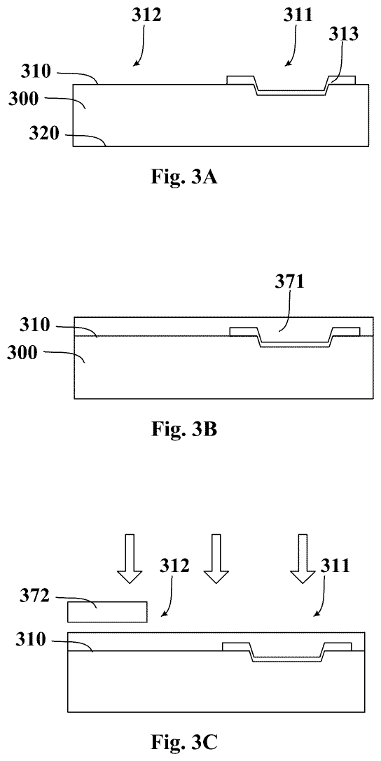

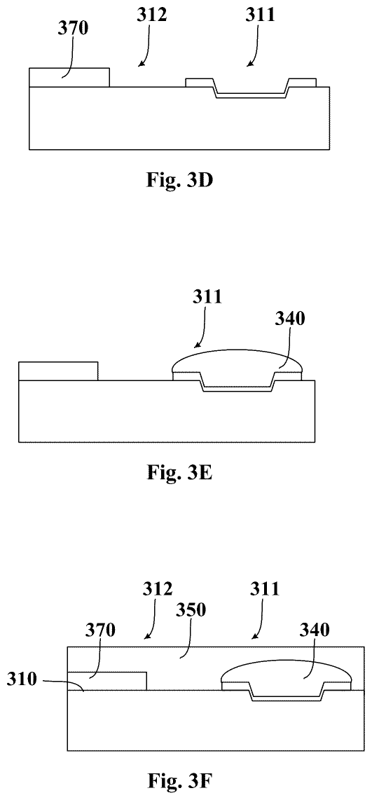

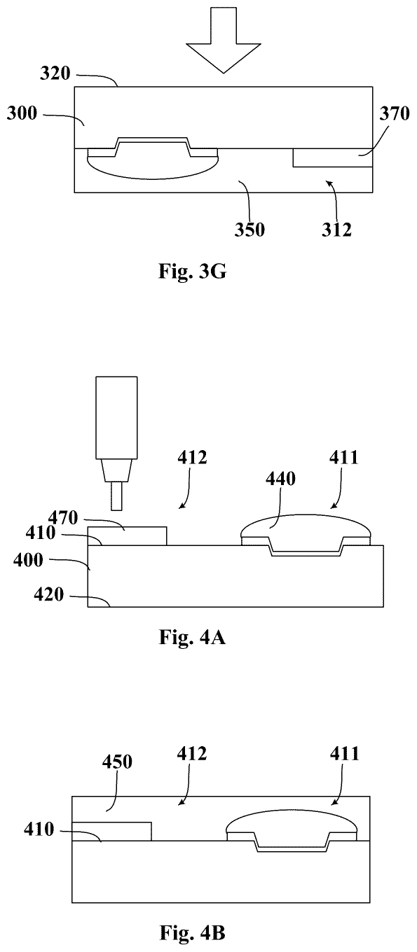

FIGS. 3A to 3G illustrate a portion of a wafer base 300 formed with a patterned photoresist layer in the steps for wafer grinding according to an embodiment of the present application.

Referring to FIG. 3A, the wafer base 300 is provided. Similar as the wafer base 100 and 200 illustrated before with reference to FIGS. 1A to 1C and 2A to 2C, the wafer base 300 includes a front side 310 and a back side 320 opposite to each other. The front side 310 includes a solder ball area 311 and an annular peripheral area 312 surrounding the solder ball area 311. Preferably, the solder ball area 311 is not yet formed with solder balls, and a last under ball metal (UBM) layer 313 is exposed.

In some embodiments, the wafer base 300 may include a base substrate material such as silicon, germanium, aluminum phosphide, aluminum arsenide, gallium arsenide, gallium nitride, indium phosphide, silicon carbide, or other bulk semiconductor material for structural support. A plurality of semiconductor units formed thereon (not shown) can be separated by a non-active, inter-die saw street into individual semiconductor dice later after the grinding process.

Referring to FIGS. 3B to 3D, a patterned photoresist layer 370 is then formed. The patterned photoresist layer 370 at least partially covers the annular peripheral area 312 but exposes the solder ball area 311. Specifically, as shown in FIG. 3B, a photoresist layer 371 made of a positive photoresist material is formed to cover the front side 310 of the wafer base 300. Then, as shown in FIG. 3C, a mask 372 can be disposed above the photoresist layer to at least partially cover the annular peripheral area 312, but expose the solder ball area 311. Then an exposure process using such as an ultraviolet laser source may be performed to the photoresist layer through the mask 372. Further, as shown in FIG. 3D, a development process for the exposed photoresist layer is performed, and the portion of the photoresist layer 371 exposed to the ultraviolet laser source through the mask is removed, while the portion 370 of the photoresist layer 371 covered by or aligned with the mask 372 remains for subsequent steps.

It can be understood that, in some other embodiments, in order to form the patterned photoresist layer 370, a negative photoresist material and a mask having a complementary covering area from the mask 372 mentioned above can also be used.

It can also be understood that, the patterned photoresist layer 370 may have different forms. For example, the patterned photoresist layer 370 may fully cover the annular peripheral area 312, expose or cover the saw streets of the wafer base 300 in the annular peripheral area 312. In some other embodiments, a distance between an outer boundary of the annular peripheral area 312 and an outer boundary of the patterned photoresist layer 370 ranges from 0.5 mm to 1.5 mm, preferably equal to 1 mm. In some embodiments, a distance between an inner boundary of the annular peripheral area 312 and an inner boundary of the patterned photoresist layer 370 ranges from 0.5 mm and 1.5 mm, preferably equal to 1 mm. As mentioned above, in some embodiments, a height of the patterned photoresist layer 370 may range from ½ to ¾ of an average height of the solder balls 340 to be formed. The advantages of such configurations have been described above and will not be repeated herein.

It can be understood that, in order to control a pattern of the patterned photoresist layer 370, a masking and lithography process can be performed. It can also be understood that, in order to control a height of the patterned photoresist layer 370, a predetermined amount of photoresist material may be pre-calculated to cover the front surface 310 of the wafer base 300 and achieve the predetermined height.

Referring to FIG. 3E, solder balls 340 are formed on the solder ball area 311 using an evaporation, electrolytic plating, electroless plating, ball drop, or screen printing process. The material of the solder balls 340 can be Al, Sn, Ni, Au, Ag, Pb, Bi, Cu, solder, and combinations thereof, with an optional flux solution.

Referring to FIG. 3F, a back grinding tape 350 is attached on the front side 310, covering both the solder ball area 311 and the annular peripheral area 312. The back grinding tape 350 can include materials such as epoxy, or acryl materials having adhesive characteristics, the back grinding tape 350 can be deposited using a spin coating or a screen printing method.

Referring to FIG. 3G, a back grinding process is performed to the back side 320 of the wafer base 300. Since the patterned photoresist layer 370 is disposed at the edge of the wafer base 300, the edge of the wafer 300 is fully supported during the grinding process. Therefore, grinding impact at the edge can be reduced. In some embodiments, the back grinding process can include using a grind wheel repeatedly to remove a predetermined amount of material from the back side 320 of the wafer base 300. It can be understood that, after the back grinding process, the back grinding tape 350 can be removed.

Since the location of the patterned photoresist layer 370 is in the annular peripheral area 312, that is, the patterned photoresist layer 370 is in a non-active area, the patterned photoresist layer 370 would not affect the electrical function of the semiconductor units, and the patterned photoresist layer 370 does not need to be removed from the wafer base 300.

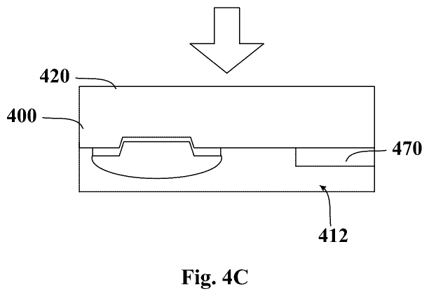

As mentioned above, thermosetting material is also suitable material for edge support of the wafer base. FIGS. 4A to 4C illustrate a portion of a wafer base 400 formed with a patterned thermosetting material layer as edge support in the steps for wafer grinding. Similar configuration may refer to the above embodiments and would not be repeated herein.

Referring to FIG. 4A, the wafer base 400 having a front side 410 and a back side 420 is provided. The front side 410 includes a solder ball area 411 and an annular peripheral area 412 surrounding the solder ball area 411, and the solder ball area 411 is formed with solder balls 440.

Then, a patterned thermosetting material layer 470 can be formed on the front side 410 of the wafer base 400. The patterned thermosetting material layer 470 at least partially covers the annular peripheral area 412 but exposes the solder ball area 411. In some embodiments, the patterned thermosetting material layer 470 can be made of epoxy resin material. The patterned thermosetting material layer 470 can be formed by dispensing thermosetting material on the front side 410 at desired locations and then curing using heating, for example.

Similar as the embodiments illustrated above with reference to FIGS. 3A to 3G, the patterned thermosetting material layer 470 can be formed to fully cover or expose the saw street of the semiconductor units of the wafer base 400. In some other embodiments, a distance between an outer boundary of the annular peripheral area 412 and an outer boundary of the patterned thermosetting material layer 470 ranges from 0.5 mm to 1.5 mm, preferably equal to 1 mm. In some embodiments, a distance between an inner boundary of the annular peripheral area 412 and an inner boundary of the patterned thermosetting material layer 470 ranges from 0.5 mm and 1.5 mm, preferably equal to 1 mm. As mentioned above, in some embodiments, a height of the patterned thermosetting material layer 470 may range from ½ to ¾ of an average height of the solder balls 440 to be formed. The advantages of such configurations are illustrated above and will not be repeated herein.

It can be understood that, in order to control a pattern of the patterned thermosetting material layer 470, a stencil and/or mesh plate can be used. It can also be understood that, in order to control a height of the patterned thermosetting material layer 470, a predetermined amount of thermosetting material may be pre-calculated to cover the front surface 410 of the wafer base 400 and achieve the predetermined height.

Referring to FIG. 4B, similar as the embodiment shown in FIG. 3F, a back grinding tape 450 is attached on the front side 410 to cover both the solder ball area 411 and the annular peripheral area 412. Referring to FIG. 4C, similar as the embodiment shown in FIG. 3G, a back grinding process is performed to the back side 420 of the wafer base 400.

Since the location of the patterned thermosetting material layer 470 is in the annular peripheral area 412, that is, the patterned thermosetting material layer 470 is in a non-active area, the patterned thermosetting material layer 370 would not affect the electrical function of the semiconductor units, and the patterned thermosetting material layer 470 does not need to be removed from the wafer base 400.

It can be understood that, the present application provides methods for forming edge support for a wafer, thereby the wafer undergoing a back grinding process can have a lower risk of edge chipping, and the general cost for back grinding can be reduced.

The discussion herein included numerous illustrative figures that showed various portions of a semiconductor wafer and method of wafer grinding. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A wafer grinding method, comprising:
providing a wafer base comprising a front side and a back side, wherein the front side comprises a solder ball area and an annular peripheral area surrounding the solder ball area;
forming a patterned photoresist layer on the front side of the wafer base, wherein the patterned photoresist layer at least partially covers the annular peripheral area but exposes the solder ball area;
forming solder balls on the solder ball area;
attaching a back grinding tape on the front side to cover both the solder ball area and the annular peripheral area; and
performing a back grinding process on the back side of the wafer base.

2. The method of claim 1, wherein a distance between an outer boundary of the annular peripheral area and an outer boundary of the patterned photoresist layer ranges from 0.5 mm to 1.5 mm.

3. The method of claim 1, wherein a distance between an inner boundary of the annular peripheral area and an inner boundary of the patterned photoresist layer ranges from 0.5 mm and 1.5 mm.

4. The method of claim 1, wherein a distance between an outer boundary of the annular peripheral area and an outer boundary of the patterned photoresist layer is 1 mm, and a distance between an inner boundary of the annular peripheral area and an inner boundary of the patterned photoresist layer is 1 mm.

5. The method of claim 1, wherein the patterned photoresist layer exposes or covers saw streets of the wafer base in the annular peripheral area.

6. The method of claim 1, wherein a height of the patterned photoresist layer ranges from ½ to ¾ of an average height of the solder balls.

7. A wafer grinding method, comprising:
providing a wafer base comprising a front side and a back side, wherein the front side comprises a solder ball area and an annular peripheral area surrounding the solder ball area, wherein the solder ball area is formed with solder balls;
forming a patterned thermosetting material layer on the front side of the wafer base, wherein the patterned thermosetting material layer at least partially covers the annular peripheral area but exposes the solder ball area;
attaching a back grinding tape on the front side to cover both the solder ball area and the annular peripheral area; and
performing a back grinding process on the back side of the wafer base.

8. The method of claim 7, wherein forming a patterned thermosetting material layer on the front side of the wafer base comprises: dispensing thermosetting material on the front side of the wafer base.

9. The method of claim 7, wherein a distance between an outer boundary of the annular peripheral area and an outer boundary of the patterned thermosetting material layer ranges from 0.5 mm and 1.5 mm.

10. The method of claim 7, wherein a distance between an inner boundary of the annular peripheral area and an inner boundary of the patterned thermosetting material layer ranges from 0.5 mm and 1.5 mm.

11. The method of claim 7, wherein a distance between an outer boundary of the annular peripheral area and an outer boundary of the patterned thermosetting material layer is 1 mm, and a distance between an inner boundary of the annular peripheral area and an inner boundary of the patterned thermosetting material layer is 1 mm.

12. The method of claim 7, wherein the patterned thermosetting material layer exposes or covers saw streets of the wafer base.

13. The method of claim 7, wherein a height of the patterned thermosetting material layer ranges from ½ to ¾ of an average height of the solder balls.

14. The method of claim 7, wherein the patterned thermosetting material layer is made of epoxy resin material.
